(19) United States
(12) Patent Application Publication
(10) Pub. No.: US 2012/0294073 A1
(43) Pub. Date: Nov. 22, 2012

(54) METHOD OF DRIVING PHASE CHANGE MEMORY DEVICE CAPABLE OF REDUCING HEAT DISTURBANCE

(76) Inventor: Se Ho LEE, Gyeonggi-do (KR)

(21) Appl. No.: 13/489,590

(22) Filed: Jun. 6, 2012

Related U.S. Application Data
(63) Continuation-in-part of application No. 12/782,849, filed on May 19, 2010, now abandoned.

(30) Foreign Application Priority Data
Jan. 29, 2010 (KR) 10-2010-0008694

(51) Int. Cl. G11C 11/00

(52) U.S. Cl. 365/163; 365/148

(57) ABSTRACT

A method of driving phase change memory device which reduces or prevents unwanted heat disturbances from interfering with memory states in adjacent memory cells is presented. The phase change memory cells are disposed at word and bit line intersections. The method includes collectively erasing all of the memory cells as a unit in the bit line into a reset state. The method then includes individually programming only selected memory cells of the memory cells into set states.

### CROSS-REFERENCES TO RELATED APPLICATION

The present application claims priority under 35 U.S.C. 119(a) to Korean application number 10-2010-0008694, filed on Jan. 29, 2010, in the Korean Patent Office, which is incorporated by reference in its entirety as if set forth in full.

### BACKGROUND OF THE INVENTION

1. Technical Field

The inventive concept relates to a non-volatile semiconductor memory device and, more particularly, to a method of driving phase change memory device capable of reducing a disturbance.

2. Related Art

Nonvolatile memory devices maintain data stored therein, even when the power is off. Accordingly nonvolatile memory devices are widely used in computers, mobile telecommunication systems and memory cards.

Typically, flash memory devices are widely used as the nonvolatile memory devices. Flash memory devices typically adopt memory cells that have stack gate structures. So as to improve the reliability and the programming efficiency of a memory cell in the flash memory device, the film quality of a tunneling oxide should be improved and a coupling ratio of a memory cell should be increased.

Currently, new nonvolatile memory devices, for example phase change memory devices have been suggested as suitable to substitutes for the flash memory devices. A unit cell of the phase change memory cell includes a switching device connected to an intersection of a word line and a bit line and a data storage element serially connected to the switching device. The data storage element includes a lower electrode electrically connected to the switching device, a phase change material pattern on the lower electrode and an upper electrode on the phase change material pattern. In general, the bottom electrode serves as a heater.

The phase change memory device generate electrical resistive heat, i.e., Joule heat, at the interface between the phase change material pattern and the bottom electrode, when the writing current flows through the switching device and the bottom electrode. The Joule heat transforms the phase change material pattern into an amorphous state or a crystalline state.

Typically, the phase change material pattern is patterned to be overlapped with a bit line. Due to this, a heat disturbance, i.e., heat convection/diffusion, may occur between adjacent phase change material patterns arranged on the same bit line and result in interfering with changing the crystalline/amorphous states in adjacent memory cells in the bit line. In particular this problem becomes more serious as the distance between cells becomes narrower due to higher integration density of the semiconductor devices and as a result the problem with heat disturbance becomes more and more serious.

For example, referring to FIG. 1, if a cell A is in a “0” state of low resistance and “1” of high resistance is written in a cell B adjacent to the cell A, the resultant Joule heat is generated at the interface between the lower electrode 10 and the phase change material layer 20 of the cell B by the writing current and it melts the phase change material layer 20. At this time, the phase change material layer of adjacent cell A is coupled to the phase change material layer of the cell B so that the heat is transferred to the cell A and the temperature in the heat-transferred area is increased. As a result, it leads to increase the resistance of the cell which is in the “0” state of low resistance. Accordingly, the cell A of the “0” state loses the original date and the cell A did not work as a memory cell.

The heat disturbance is chronic problem of the high integration phase change memory device. So as to solve the problem, various methods such as a phase change material pattern of a confined structure have been suggested. However, it is difficult to remove the disturbance between memory cells on the same bit line. Particularly, to reset a memory cell adjacent to the reset memory cell on the same bit line actually causes malfunction due to the disturbance.

### SUMMARY

According to one exemplary embodiment provides a method of driving a phase change memory device which sets or resets a plurality of memory cells disposed at intersections of a plurality of word lines and a plurality of bit lines crossed with each other, includes collectively erasing the plurality of memory cells to a reset state as the unit of bit line and individually programming selected memory cells of the plurality of memory cells to a set state.

According to another exemplary embodiment provides a method of driving a phase change memory device which sets or resets a plurality of memory cells disposed at intersections of a plurality of word lines and a plurality of bit lines crossed with each other, includes resetting the plurality of memory cells as the unit of bit line under the state of enabling all the word lines and selectively setting selected memory cells of the reset memory cells.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a sectional view of a conventional phase change memory device illustrating thermal disturbance;

FIG. 2 is a plane view of a phase change memory device illustrating a driving method according to an exemplary embodiment;

FIG. 3 is a plane view of a phase change memory device according to another exemplary embodiment;

FIG. 4 is a plane view of a phase change memory device illustrating a driving method according to an exemplary embodiment;

FIG. 5 is a plane view of a phase change memory device illustrating a driving method according to an exemplary embodiment;

FIG. 6 is a timing diagram showing a set pulse and a reset pulse of the phase change memory device;

FIG.7 is a plane view of the phase change memory device illustrating a comparing example; and

FIG. 8 is a timing diagram showing word line pulses and bit line pulses of the phase change memory device according to an exemplary embodiment.

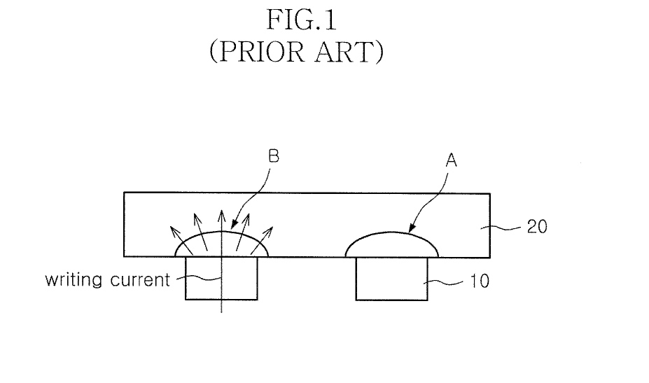

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements.

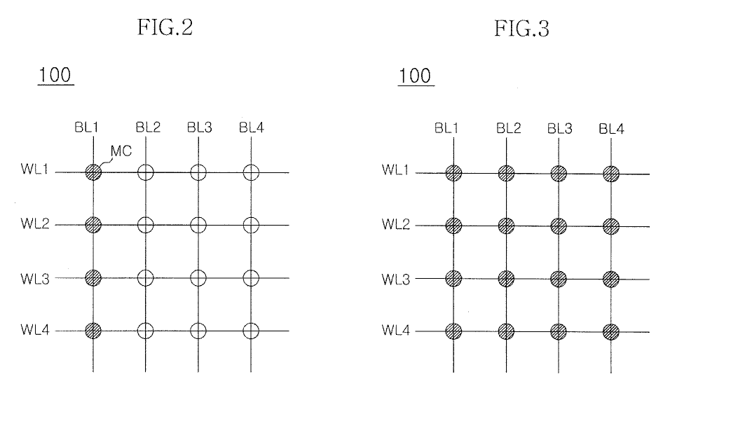

Referring to FIG. 2, a phase change memory device 100 in an exemplary embodiment includes a plurality of word lines WL1 to WL4 and a plurality of bit lines BL1 to BL4 which are crossed with each other. For convenience, the exemplary embodiment may illustrate 4 word lines and 4 bit lines. A plurality of phase change memory cells are arranged at intersections of the plurality of word lines WL1 to WL4 and the plurality of bit lines BL1 to BL4. Herein, each of the phase change memory cells MC designates change portion of a phase change material layer extended in parallel to the bit lines BL1 to BL4.

Referring to FIG. 3, the phase change memory cells MC are sequentially erased to a reset state as the unit of one bit line. The erase operation is performed by sequentially applying a reset pulse to a corresponding bit line of the bit lines BL1 to BL4 under the state of enabling all the first to the fourth word lines WL1 to WL4. In FIGS. 2 and 3, memory cells MC erased to the reset state are represented as circles with diagonal has marks and memory cells MC programmed to the set state are represented by empty circles.

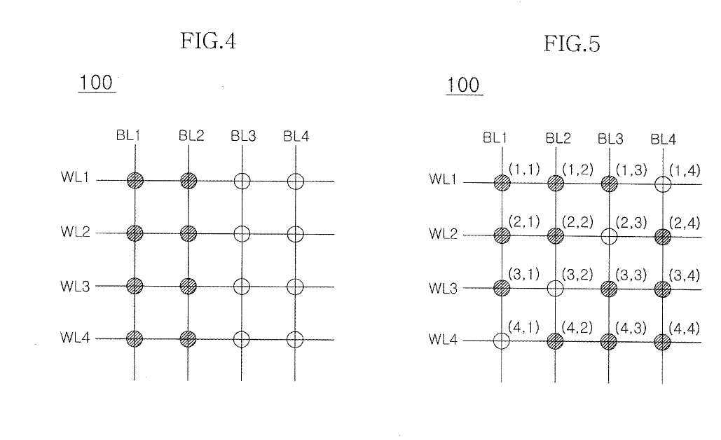

In the erase operation, as shown in FIG. 4, the phase change memory cells MC may be erased to the reset state as the unit of two bit lines BL1/BL2 and BL3/BL4.

As described above, all the phase change memory cells MC are erased to the reset as the unit of one or two bit lines and then as shown in FIG. 4, selected memory cells are individually programmed to a set state.

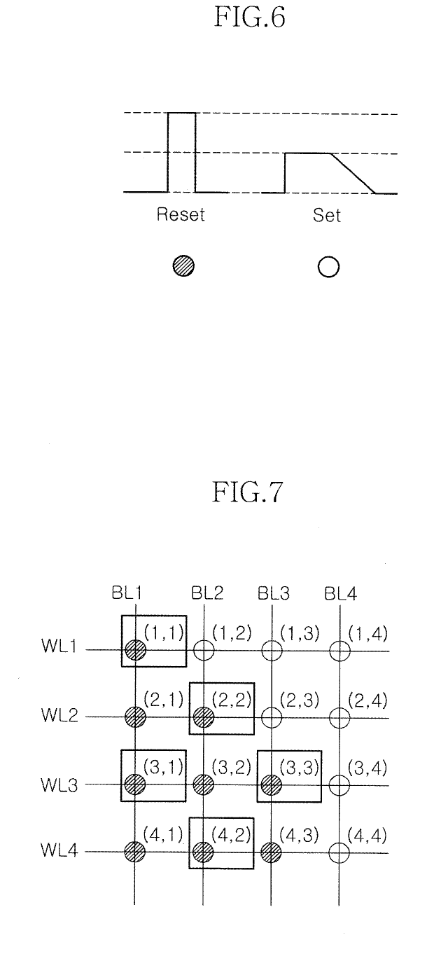

At this time, referring to FIG. 6, it understood that the voltage to program a set state in the memory cell is relatively lower than the voltage needed to erase the set state into a reset state. Accordingly, it is known that the programming operation for programming a set state from a reset state is not adversely affected by the heat disturbance problem.

According to this, if selected memory cells which have been already been previously erased into the reset state then programming these selected memory cells into the set state will not adversely affect the state of adjacent cells.

In the situation where all of the memory cells MC are erased into the reset state, programming the memory cell MC at coordinate (3,2) into a set state will not adversely affect the reset states in adjacent memory cells because the intensity of the set pulse is lower than the intensity of the reset pulse. As a consequence, adjacent memory cells in the reset state are not affected by the thermal disturbance brought about by writing the memory cell MC at coordinate (3,2) into a set state. Furthermore, since the voltage needed to write a memory cell MC from a reset state into a set state is low then it also follows that if adjacent memory cells are already in a set state then these adjacent cells will also not be adversely affected by the thermal disturbance because the set voltage is lower than the reset voltage. Also it is understood that the memory cell MC at coordinate (3,2) is at the intersection of the third word line WL3 and the second bit line BL2.

At this time, in the situation of selectively enabling a word line of the word lines WL1 to WL4 connected to the corresponding memory cell MC, it may selectively program only the selected memory cell MC by applying the set pulse to a bit line of the bit line BL1 to BL4 connected the selected memory cell MC.

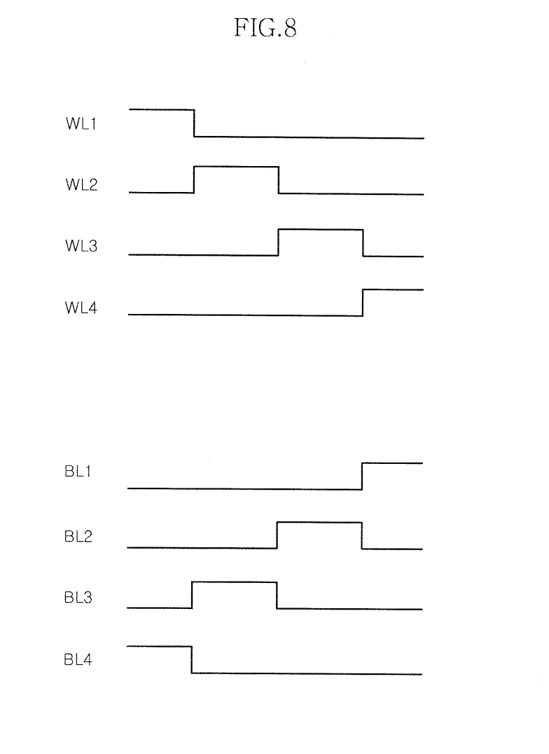

For example, the memory cell MC may be sequentially programmed in diagonal direction, as shown in FIG. 5. In this case, the word lines WL1 to WL4 are sequentially enabled and the bit lines BL1 to BL4 are sequentially enabled, as shown in FIG. 8.

Further, the memory cell MC may be randomly programmed after all memory cells are erased(or resetted). That is, a random word line and a random bit line are enabled, respectively, a random memory cell which is positioned corresponding a cross section of the random word line and the random bit line may be programmed, after all of the memory cells .The driving method of the phase change memory cell will be more easily understood by explaining the reverse case.

That is, as shown in FIG.7, suppose that the memory cells MC corresponding to coordinates (1,1) and/or (1,3) are to the reset, when it erases the memory cell MC corresponding to a coordinate (1,2), the state of the memory cells MC corresponding to the coordinates (1,1) and/or (1,3) are changed by the thermal disturbance. Similarly, in case where the memory cells MC corresponding to coordinates (2,2) and/or (2,4) are to the reset state, when it erases the memory cell MC corresponding to a coordinate (2,3), the memory cells MC corresponding to the coordinates (2,2) and/or (2,4) are affected by the thermal disturbance. The boxed portions of the drawings designate the memory cells affected by the thermal disturbance.

On the other hands, in the exemplary embodiment, the memory cells MC are collectively erased as the unit of bit line that is, the word lines WL1 to WL4 connected to corresponding bit line BL1, BL2, BL3 or BL4 are simultaneously enabled. Therefore, the erase operation is simultaneously performed, so that adjacent memory cell is not affected by the thermal disturbance. In programming, the memory cells are programmed by the set pulse lower than the reset pulse as the unit of memory cell so that the disturbance is not generated.

As described above, the exemplary embodiment makes the whole memory cells to the collective reset state and then selectively makes the selected memory cells to the set state so that the thermal disturbance between the memory cells on the same bit line can be protected against.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A method of driving a phase change memory device which sets or resets a plurality of memory cells disposed at intersections of a plurality of word lines and a plurality of bit lines crossed with each other, comprising:
(a) collectively erasing all memory cells in a corresponding bit line into a reset state; and
(b) sequentially programming selected memory cells of the erased memory cells having the reset state of the corresponding bit line into a set state.

2. The method of claim 1, wherein the collectively erasing comprises simultaneously erasing all memory cells corresponding to one or two bit lines.

3. The method of claim 2, wherein the collectively erasing comprises applying a reset pulse to the corresponding bit line.

4. The method of claim 1, wherein the programming comprises applying a set pulse to the selected memory cells of the erased memory cells of the corresponding bit line.

5. A method of driving a phase change memory device which sets or resets a plurality of memory cells disposed at intersections of a plurality of word lines and a plurality of bit lines crossed with each other, comprising:
(a) resetting all memory cells along a corresponding of bit line into a reset state when the word lines are enabled; and
(b) sequentially setting selected memory cells which are phase changed into the reset state along the corresponding bit line randomly.

6. The method of claim 5, wherein resetting all memory cells along the corresponding bit line comprises applying a reset pulse at the corresponding bit line.

7. The method of claim 5, wherein resetting all memory cells along the corresponding bit line comprises applying a reset pulse at two bit lines.

8. The method of claim 5, wherein selectively setting selected memory cells comprises applying a set pulse only at the selected memory cells when corresponding word lines are enabled which are connected to the selected memory cells.

9. The method of claim 4, wherein the selected memory cells are arranged in a diagonal direction,
a plurality of word lines and a plurality of bit lines connected to the selected memory cells are sequentially enabled, respectively.

10. The method of claim 4, wherein the selected memory cells are arranged randomly,
a plurality of word lines and a plurality of bit lines connected to the selected memory cells are sequentially enabled, respectively.
